(19) United States
(12) Patent Application Publication
(10) Pub. No.: US 2008/0035933 A1
(43) Pub. Date: Feb. 14, 2008

(54) THIN FILM TRANSISTOR ARRAY SUBSTRATE, MANUFACTURING METHOD THEREOF AND DISPLAY DEVICE

(75) Inventors: Hitoshi Nagata, Tokyo (JP); Atsushi Endo, Tokyo (JP); Shinsuke Yura, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/833,586

(22) Filed: Aug. 3, 2007

(30) Foreign Application Priority Data
Aug. 9, 2006 (JP) 2006-216502

(51) Int. Cl. H01L 29/04; H01L 21/82

(52) U.S. Cl. 257/72; 438/128; 257/E29.275; 257/E21.535

(57) ABSTRACT

A thin film transistor array substrate includes a polysilicon layer having a predetermined pattern shape formed over a substrate, a first gate insulating film provided over the substrate and on the surface of the polysilicon layer and having a same polished surface as the surface of the polysilicon layer and a second gate insulating film formed to cover the polysilicon layer and the first gate insulating film.

### BACKGROUND OF THE INVENTION

1. Field of the Invention

The present invention relates to a thin film transistor array substrate, a manufacturing method thereof and a display device.

2. Description of Related Art

Organic EL display devices and liquid crystal display devices are formed over an insulating substrate such as a glass substrate. These display devices are dramatically improving their performance by utilizing low-temperature polycrystalline silicon (LTPS) thin film transistor (TFT) By using LTPSTFT for forming peripheral circuits of the display device, an IC and IC mounting board are used less. Therefore, the peripherals of the display device can be simplified, thereby achieving a display device in a narrow frame with high reliability. Furthermore in a liquid crystal display device, this not only reduces the capacity of a switching Tr (transistor) for each pixel but also reduces the area of a storage capacitor connected to a drain side. Thus, a liquid crystal display device with high resolution and high aperture ratio can be achieved. Therefore, the LTPSTFT plays a leading role in high resolution liquid crystal display device of QVGA (pixel count: 240×320) and VGA (pixel count: 480×640) for a small size panel used for a cellular phone or the like.

FIGS. 4A and 4B are cross-sectional diagrams showing the configuration of a conventional LTPSTFT. FIG. 4A is a cross-sectional diagram cut along in the direction where source/drain regions are formed. FIG. 4B is a cross-sectional diagram cut along in the direction perpendicular to FIG. 4A. As shown in FIG. 4A, in a conventional TFT, a polysilicon layer 2 including a source region 21, drain region 22 and channel region 23 is formed over an insulating substrate 1. Moreover, a gate insulating film 3 is formed over the polysilicon layer 2. A gate electrode 4 is formed in a portion to cover the channel region 23 over the gate insulating film 3.

As LTPSTFT polycrystallizes a silicon layer in a low-temperature process under 500 degree Celsius, a surface heating (laser annealing) by laser is used. The surface of the polysilicon layer 2 after the polycrystallization becomes rough as shown in FIGS. 4A and 4B. The roughness is considered to be caused by a crystal grain boundary of the polycrystalline silicon (polysilicon). Although depending on a wavelength of the laser to irradiate, surface condition of the irradiated surface and atmosphere at the time of irradiation, usually a peak to valley value for the surface roughness of the polysilicon layer 2 in the LTPSTFT is approx. 10 to 40 nm. The thickness of the gate insulating film 3 formed over the polysilicon layer 2 is approx. 100 nm, which is close to the surface roughness of the polysilicon layer 2. That is, the gate insulating film 3 is thinner over the projecting portions of the polysilicon layer 2, as shown in FIGS. 4A and 4B. When driving the TFT, charges are concentrated in the portion having thin gate insulating film 3, thereby causing a failure in a gate withstand voltage. As described above, the projections on the surface of the polysilicon layer 2 is a key factor to reduce yield and reliability of LTPSTFT products.

The size of a crystal grain of the polysilicon layer 2 is determined by the wavelength and energy intensity of the laser to irradiate. By increasing the crystal grain size of the polysilicon layer 2, a higher carrier mobility and improved TFT performance can be achieved. However, as the size of a crystal grain increases, the surface roughness becomes greater. In order to further improve the TFT characteristics, the silicon crystal grain size is further increased and the film thickness of the gate insulating film 3 is further reduced. Due to this, the projections in the surface of the polysilicon film 2 are considered to be further major issue in the future.

In order to overcome such problem, a following technique is disclosed. In the conventional LTPSTFT, by further increasing the thickness of the gate insulting film 3, an absolute value of an insulating film withstand voltage is improved. However, by the increased film thickness of the gate insulating film 3, the TFT characteristics are deteriorated. That is, a threshold voltage (Vth) of TFT increases and an on current (Ion) decreases. Furthermore, even if the thickness of the gate insulating film 3 is increased, the gate insulating film is thinner over the projecting portions of the polysilicon layer 2 and charges are concentrated when driving TFTs. Therefore, it is not a countermeasure to the root cause that leads to a failure in the withstand voltage of the gate insulating film.

Moreover, in Japanese Unexamined Patent Application Publication No. 2001-274410, a technique is disclosed to increase a gate withstand voltage by a plurality of gate insulating films including a planarizing insulating film. However as described above, the projecting portions of the polysilicon layer where charges are concentrated when driving TFTs are not removed, thus it is not a fundamental solution to the failure of the gate withstand voltage. In addition, the planarizing insulating film is formed over the polysilicon layer using spinner method or the like. With this, an oxide film of a coating material is formed in the interface between the polysilicon layer and gate insulating film. Therefore it is difficult to control a trap level density in the interface and the TFT characteristics become unstable.

On the other hand, a technique disclosed in Japanese Unexamined Patent Application Publication No. 8-255916 is to remove the projections by applying a CMP (Chemical Mechanical Polishing) to the surface of the polysilicon layer after the polycrystallization. Usually the thickness of the polysilicon layer is approx. 50 nm. To directly apply a CMP process to the projections of approx. 10 to 40 nm residing on the surface of the polysilicon layer, it is difficult to control the film thickness of the polysilicon layer. Thus variations are created in the film thickness of the polysilicon layer and also in Vth of the TFT.

The threshold voltage Vth of the TFT is represented by the formula (1) (M. Miyasaka, T. Komatsu, W. Itoh, A. Yamaguchi and H. Ohshima, “Effects of Semiconductor Thickness on Poly-Crystalline Silicon Thin Film Transistors”, Jpn. J. Appl. Phys. Vol. 35 (1996), pp. 923-929).

$$\begin{matrix}Vth = {V}_{FB} + 2 {φ}_{B} + {qN}_{A} {t}_{Si} / {C}_{ox} \\ = {V}_{0} + {qN}_{A} {t}_{Si} / {C}_{ox}\end{matrix} \qquad ( 1 )$$

where

V_{FB}: Flat band voltage

ø_{B}: Fermi potential based on intrinsic Fermi level

q: Charge

N_{A}: Density of trap behaving like an acceptor

t_{Si}: Polysilicon film thickness

Cₒₓ: Gate insulating film capacitance

From the formula (1), it can be seen that the threshold voltage Vth of the TFT varies depending on the polysilicon film thickness t_{Si}.

The cross section of the polysilicon layer of the TFT is formed in a trapezoid where the width gets narrower from bottom to top with sidewall formed in taper. This is to resolve failures concerning etching residue and disconnection of a gate electrode. However there is another problem generated at the same time due to this. More specifically, tapered portions with thin film thickness are formed to the both sides of the channel region. This causes to overlap the TFT characteristics of normal film thickness portions and the TFT characteristics of the tapered portions with thin film thickness.

In the tapered portion, as seen from the formula (1)

Vth of the TFT is low. Thus, the tapered portion is turned on first in a gate voltage lower than the main normal film thickness portion. Therefore, in a drain current (logarithm)-gate voltage characteristics (Id(logarithm)-Vg characteristics: hereinafter referred to as subthreshold characteristics) shown in FIG. 5, Id rises due to an influence by the tapered portion even in a region with low Vg. However, as a channel width of the tapered portion is narrow, in a saturation region, Id flowing the tapered portion is smaller than the normal film thickness portion. Therefore, in the saturation region, the TFT characteristics of the normal film thickness portion are dominant. As described above, a hump appears in a drain current (logarithm) rising portion in the subthreshold characteristics. Furthermore, the TFT characteristics become unstable.

The present invention seeks to solve one or more of the above problems, or to improve upon those problems at least in part and provides a thin film transistor array substrate, a manufacturing method thereof and a display device with high reliability and stable performance.

### SUMMARY OF THE INVENTION

According to an embodiment of the present invention, there is provided a thin film transistor array substrate that includes a polysilicon layer having a predetermined pattern shape formed over a substrate, a first gate insulating film provided over the substrate and on a surface of the polysilicon layer and having a same polished surface as the surface of the polysilicon layer and a second gate insulating film formed to cover the polysilicon layer and the first gate insulating film.

According to another embodiment of the present invention, there is provided a thin film transistor array substrate that includes a polysilicon layer having a predetermined pattern shape formed over a substrate, a first gate insulating film provided over the substrate and on a surface of the polysilicon layer, a surface of the first gate insulating film having a substantially same height as the surface of the polysilicon layer, and a surface of the first gate insulating film over a pattern edge portion and a pattern peripheral portion of the polysilicon layer having a substantially same height as the surface of the polysilicon layer and a second gate insulating film formed to cover the polysilicon layer and the first gate insulating film.

The present invention enables to provide a thin film transistor array substrate with high reliability and stable performance, a manufacturing method thereof and a display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 shows the configuration of a TFT array substrate of a liquid crystal display device according to an embodiment of the present invention;

FIG. 2A is a plan view of the TFT according to an embodiment of the present invention;

FIG. 2B is a cross-sectional diagram taken along the line IIB-IIB of FIG. 2A;

FIG. 2C is a cross-sectional diagram taken along the line IIC-IIC of FIG. 2A;

FIGS. 3A to 3H are cross-sectional diagrams showing a manufacturing process of the TFT according to an embodiment of the present invention;

FIGS. 4A and 4B are cross-sectional diagrams of a conventional TFT; and

FIG. 5 is a graph showing a subthreshold characteristics of the TFT.

### DESCRIPTION OF THE PREFERRED EMBODIMENTS

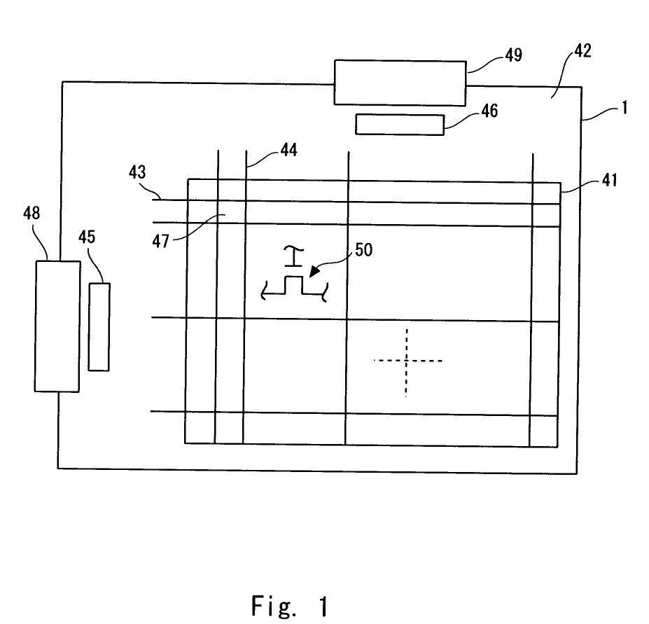

Firstly a display device incorporating a TFT array substrate according to the present invention is described hereinafter in detail with reference to FIG. 1. FIG. 1 is a front view showing the configuration of the TFT array substrate used in the display device. The display device of the present invention is explained with an example of a liquid crystal display device. However this is illustrative only and a flat panel display such as an organic EL display device can be used.

The liquid crystal display device according to the present invention includes an insulating substrate 1. The insulating substrate 1 is for example an array substrate such as a TFT array substrate. A display area 41 and a frame area 42 surrounding the display area 41 are provided to the insulating substrate 1. A plurality of gate lines (scan signal lines) 43 and a plurality of source lines (display signal lines) 44 are formed in the display area 41. The plurality of gate lines 43 are provided in parallel. Likewise, the plurality of source lines 44 are provided in parallel. The gate lines 43 and source lines 44 are formed to cross each other. The gate lines 43 and signal lines 44 are orthogonal. Moreover, an area surrounded by adjacent gate lines 43 and source lines 44 is a pixel 47. Accordingly in the insulating substrate 1, pixels 47 are arranged in matrix.

Additionally in the frame area 42 of the insulating substrate 1, a scan signal driving circuit 45 and a display signal driving circuit 46 are provided. The gate lines 43 are extended from the display area 41 to the frame area 42. Furthermore, the gate lines 43 are connected with the scan signal driving circuit 45 at the end part of the insulating substrate 1. The source lines 44 are also extended from the display area 41 to the frame area 42. The source lines 44 are connected with the display signal driving circuit 46 at the end part of the insulating substrate 1. An external line 48 is connected near the scan signal driving circuit 45. Furthermore, an external line 49 is connected near the display signal driving circuit 46. The external lines 48 and 49 are wiring boards such as FPC (Flexible Printed Circuit).

Various signals are supplied to the scan signal driving circuit 45 and display signal driving circuit 46 via the external lines 48 and 49. The scan signal driving circuit 45 supplies a gate signal (scan signal) to the gate line 43 according to an external control signal. By the gate signal, the gate lines 43 are selected sequentially. The display signal driving circuit 46 supplies a display signal to the signal lines 44 according to an external control signal or display data. This enables to supply a display voltage according to the display data to each of the pixels 47.

Inside the pixel 47, at least one TFT 50 is formed. The TFT 50 is placed near the intersection of the source line 44 and gate line 43. For example, this TFT 50 supplies the display voltage to a pixel electrode. That is, by the gate signal from the gate line 43, the TFT 50, which is a switching device, is turned on. This enables to apply the display voltage to the pixel electrode connected to a drain electrode of the TFT 50 from the signal line 44. Moreover, an electric field according to the display voltage is generated between the pixel electrode and an opposing electrode. Note that an alignment layer (not shown) is formed over the surface of the insulating substrate 1.

Furthermore, an opposing substrate (not shown) is placed opposite to the insulating substrate 1. The opposing substrate is for example a color filter substrate and placed to the visible side. Over the opposing substrate, a color filter, black matrix (BM), an opposing electrode and an alignment layer and so on are formed. Note that the opposing electrode may be placed to the insulating substrate 1 side. In addition, a liquid crystal layer is held between the insulating substrate 1 and the opposing substrate. More specifically, liquid crystal is filled between the insulating substrate 1 and the opposing substrate. Further, a polarizing plate and retardation film or the like are provided to the outside surface the insulating substrate 1 and the opposing substrate. Moreover, a backlight unit or the like is provided to the non-visible side of a liquid crystal display panel.

The liquid crystal is driven by the electric field between the pixel electrode and the opposing electrode. That is, an alignment direction of the liquid crystal between the substrates changes. This changes the polarization state of the light passing through the liquid crystal layer. To be more specific, the light that has passed the polarizing plate and became a linearly polarized light changes its polarization state by the liquid crystal layer. More specifically, the light from the backlight unit becomes a linearly polarized light by the polarizing plate provided to the array substrate side. Further, by the linearly polarized light passing through the liquid crystal layer, the polarization state changes.

Accordingly, the amount of light passing through the polarizing plate of the opposing substrate side varies according to the polarization state. More specifically, among transmitted light transmitting from the backlight unit through the liquid crystal panel, the amount of light passing through the polarizing plate of the visible side varies. The alignment direction of the liquid crystal varies according to the applied display voltage. Therefore, by controlling the display voltage, the amount of light passing through the polarizing plate of the visible side can be changed. That is, by varying the display voltage by each pixel, a desired image can be displayed.

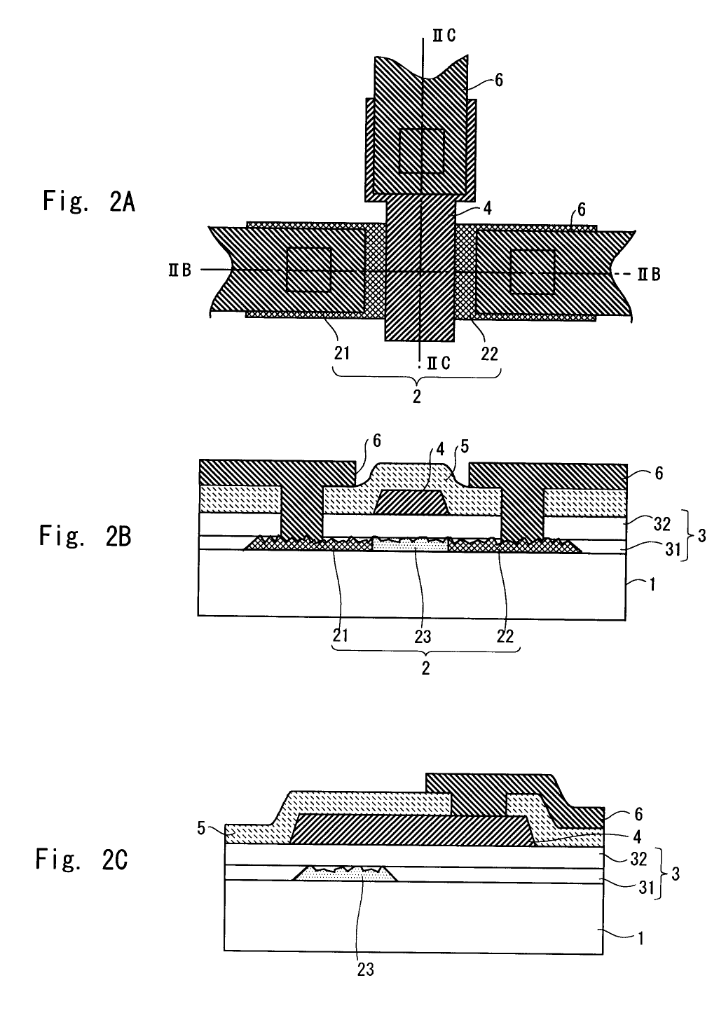

Next, the configuration of the TFT 50 is described hereinafter with reference to FIGS. 2A to 2C. FIG. 2A is a plan view schematically showing the configuration of the TFT 50 according to the present invention. FIG. 2B is a cross-sectional diagram taken along the line IIB-IIB of FIG. 2A. FIG. 2C is a cross-sectional diagram taken along the line IIC-IIC of FIG. 2A. In this example, the TFT 50 is described assuming to have a top gate structure. In an active matrix display device, the TFT 50 is placed in the pixel 47 inside the display area 41.

In FIGS. 2A to 2C, a polysilicon layer 2 is formed over the insulating substrate 1. The polysilicon layer 2 includes a source region 21 and a drain region 22 of a first conductivity type, and a channel region 23. The channel region 23 is placed between the source region 21 and the drain region 22. Furthermore, a gate insulating film 3 is formed to cover the polysilicon layer 2. A gate electrode 4 is formed oppose to the channel region 23 with the gate insulating film 3 interposed therebetween. An interlayer insulating film 5 is formed over the gate insulating film 3 and the gate electrode 4. A wiring layer 6 that makes up a circuit is connected with the source region 21, the drain region 22 and the gate electrode 4 via contact holes penetrating the interlayer insulating film 5 and gate insulating film 3.

The polysilicon layer 2 is formed by crystallizing an amorphous silicon film having a thickness of approx. 40 to 80 nm by laser annealing. The surface of the polysilicon layer 2 after the polycrystallization is rough, which is considered to be caused by crystal grain boundary of polysilicon. Furthermore, the edge portions of the polysilicon layer 2 are formed in taper. This is to secure a withstand voltage between the gate electrode 4 and the polysilicon layer 2, that is, to improve a gate withstand voltage of the TFT 50. Furthermore, it is purposed to prevent a disconnection of the gate electrode 4.

In an embodiment of the present invention, the gate insulating film 3 is formed by two layers, which are a first gate insulating film 31 on the side of the polysilicon layer 2 and a second gate insulating film 32 on the side of the gate electrode 4. After forming the first gate insulating film 31 substantially all over the insulating substrate 1 to cover the polysilicon layer 2, the whole area of the first gate insulating film 31 is removed to be substantially flat by a planarizing process such as CMP until the surface of the polysilicon layer 2 is exposed to some extent. That is, on the polysilicon layer 2, the first gate insulating film 31 fills depressions of the polysilicon layer 2 whose projections are removed to some extent. Therefore, the first gate insulating film 31 is buried in the depressed portions so that the projecting portions of the rough surface of the polysilicon layer 2 are exposed. The surface of the polysilicon layer 2 has the same polished surface as the surface of the first gate insulating film 31. Furthermore, the surface of the polysilicon layer 2 including the gate insulating film 31 after the planarizing process has the same height as the first gate insulating film 31 that is formed over the tapered edge portions of the polysilicon layer 2 and also over the insulating substrate 1. Accordingly, in the whole area of the insulating substrate 1, the surface of the first gate insulating film 31 is substantially flat. Moreover, the second gate insulating film 32 is formed over the planarly removed surface including the polysilicon layer 2 and the first gate insulating film 31.

Additionally, the pattern edge portion of the polysilicon layer 2 is formed in taper. Thus in the polysilicon layer 2, the polysilicon layer 2 is thinner in the pattern edge portions as compared to the central portion. Therefore, in the tapered pattern edge portions of the polysilicon layer 2, the polysilicon layer 2 is not exposed from the first gate insulating film 31. Further, on the pattern edge portion of the polysilicon layer 2, the surface of the first gate insulating film 31 has substantially the same height as the surface of the central portion of the polysilicon layer 2. Furthermore, on the pattern edge portions of the polysilicon layer 2, the surface of the first gate insulating film 31 has substantially the same height as the surface of the first gate insulating film 31 in the pattern peripheral part which is outside the patter of the polysilicon layer 2. The second gate insulating film 32 is provided to be in contact with the surface of the polysilicon layer 2. The distance from the surface of the insulating substrate 1 is referred to as a height here.

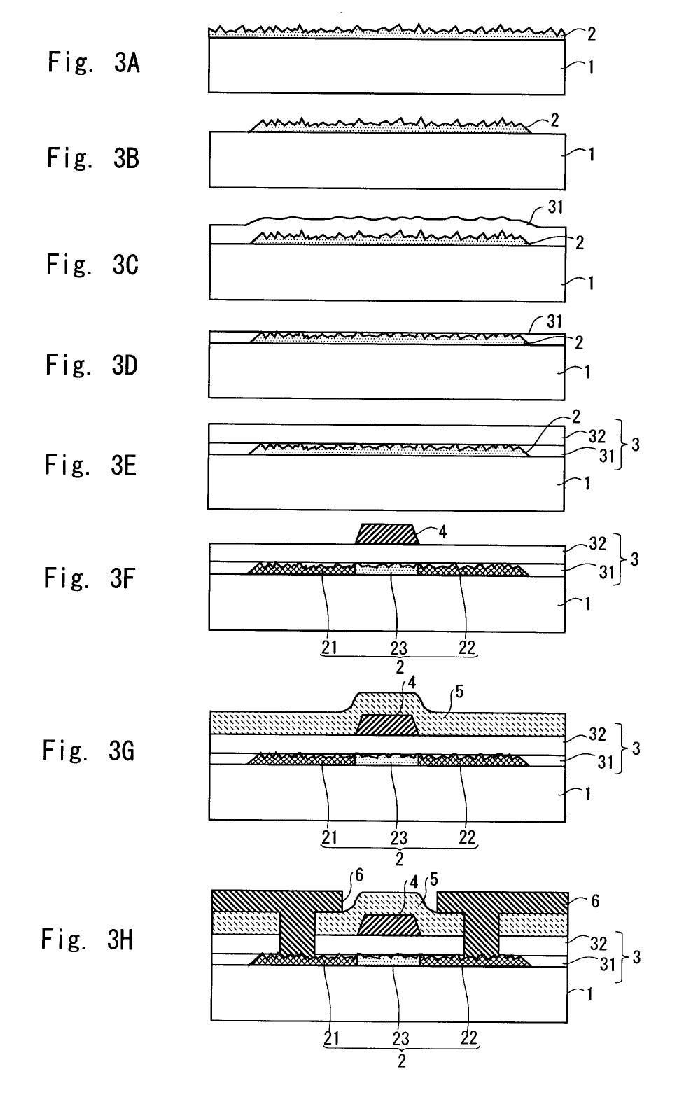

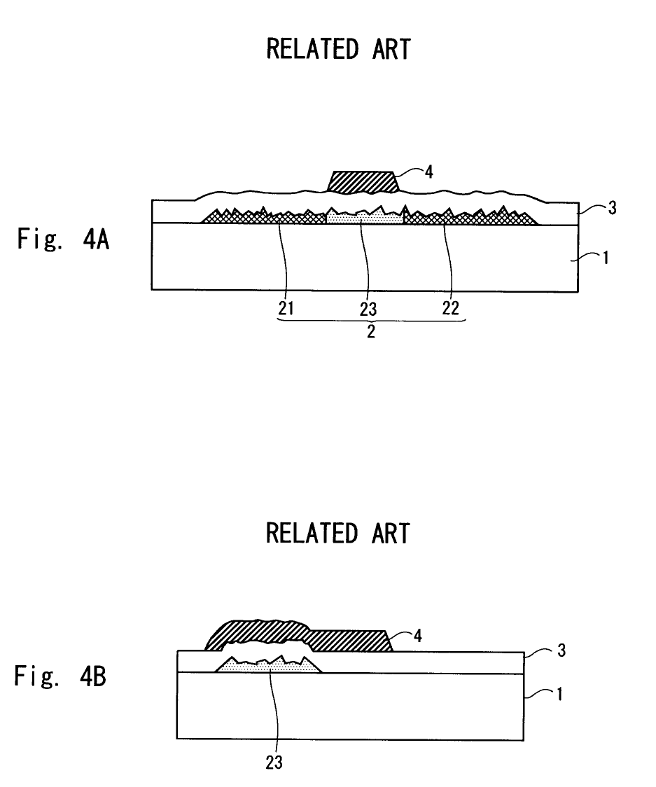

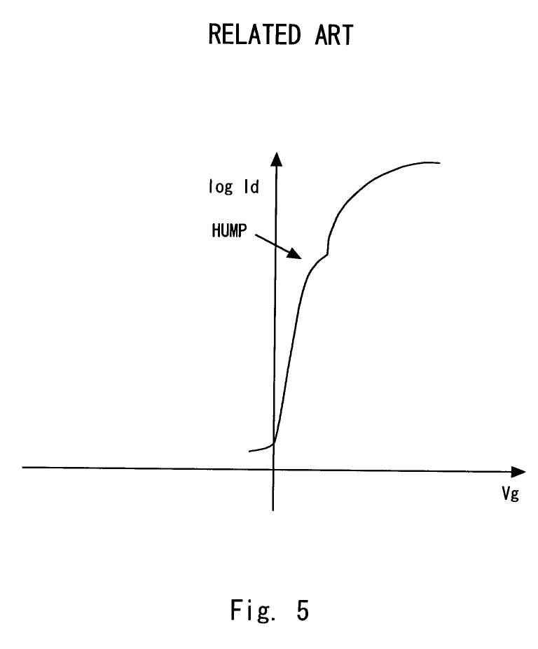

Next, a manufacturing process of the TFT 50 of this embodiment is described hereinafter in detail with reference to FIGS. 3A to 3H. FIGS. 3A to 3H are cross-sectional diagrams of the TFT according to the manufacturing process of this embodiment, showing the configuration taken along the line IIB-IIB of FIG. 2A.

Firstly, an amorphous silicon film is formed by CVD method over the insulating substrate 1 that is made of glass, for example. LPCVD (Low Pressure Chemical Vapor Deposition) method or PECVD (Plasma Enhanced Chemical Vapor Deposition) method is used. Generally the LPCVD method is able to form an amorphous silicon film more stable than by the PECVD method, however is inferior to the PECVD method in terms of productivity. As the amorphous silicon film formed by the PECVD method contains a large amount of hydrogen, the hydrogen may be bumping at a laser annealing and the film may be destroyed. Therefore, in order to reduce the hydrogen content, a heat treatment at 350 degree Celsius or higher is applied before laser annealing. After that, the amorphous silicon is polycrystallized by laser annealing or the like.

In the laser annealing, a pulse laser is irradiated for several times to crystallize the silicon. An optical absorptance of silicon crystals at a laser annealing decreases as the wavelength of the laser increases. Therefore, when using an excimer laser (wavelength: 308 nm), silicon that is crystallized in a previous irradiation is remelted. On the other hand, when using a YAG2ω laser (wavelength: 532 nm), silicon crystals generated in the previous irradiation are slow to be melted and melted non-crystallized (amorphous) portions are crystallized with these crystals as a core. Therefore, in order to achieve crystals with larger grain size, it is desirable to use a YAG2ω laser (S. Yura, A. Sono, T. Okamoto, Y. Sato, T. Kojima, J. Nishimae, M. Inoue and K. Motonami, “Crystallization of Amorphous-Si Films by Pulsed YAG2ω Green Laser for Polycrystalline Si TFT Fabrication”, Journal of the Society for Information Display Vol. 13 Iss. 10 (2005), pp. 823-827). Alternatively, a pulse laser may be used.

The surface of the polysilicon layer 2 that is poly crystallized as above becomes rough as shown in FIG. 3A. In particular, when increasing silicon crystal grain size, the roughness at the crystal grain boundary portion becomes greater. At this time, the depressions and projections on the surface of the polysilicon layer 2 may become as large as the film thickness of the polysilicon layer 2. Before laser annealing, by removing a natural oxide film over the surface of the amorphous silicon film by hydrofluoric acid, the roughness formed on the surface of the polysilicon layer 2 is reduced. Furthermore, by making the surface of the amorphous silicon film under inert atmosphere such as nitrogen at the time of a laser irradiation, the roughness on the surface of the polysilicon layer 2 is reduced.

Note that the following protection film may be provided between the insulating substrate 1 and the polysilicon layer 2. Preferably, a first protection film (not shown) for preventing a diffusion of a contaminant from the insulating substrate 1 is formed to the insulating substrate 1 side and a second protection film (not shown) that hardly generates a trap level in the interface with the polysilicon layer 2 is formed to the polysilicon layer 2 side. For example, the first protection film is assumed to be a silicon nitride film and the second protection film is assumed to be a silicon oxide film. In this case, these protection films are formed before forming the amorphous silicon film.

Next, as shown in FIG. 3B, the polysilicon layer 2 is processed to be in a predetermined shape by photo-etching or the like. For example, it is processed by a plasma etching or RIE (Reactive Ion Etching) using fluorine compound gas such as CF₄. Here, etching conditions are adjusted so that the edge shape of the polysilicon layer 2 to be in taper as in FIG. 3B. By making the edge portions of the polysilicon layer 2 formed in taper, it is possible to improve the gate withstand voltage of the TFT 50 and also resolves the failures regarding disconnections of the gate electrode.

After that as shown in FIG. 3C, the first gate insulating film 31 is formed over the insulating substrate 1 where the polysilicon layer 2 is formed. At this time, the first gate insulating film 31 must be thicker than the polysilicon layer 2. For example, an average film thickness of the polysilicon layer 2 is made to be approx. 60 nm and the thickness of the first gate insulating film 31 is made to be approx. 80 nm. Moreover, the first gate insulating film 31 is preferably an oxide film containing a large amount of hydrogen so as to reduce trap level density in the interface with the polysilicon layer 2. For example, when using the plasma enriched CVD by TEOS (Tetra Ethyl Ortho Silicate) and oxygen, a silicon oxide film containing a hydrogen content of about 4 mol % can be formed (A. M. Nguyen and S. P. Murarka, “Properties of chemical vapor deposited tetraethylorthosilicate oxides: Correlation with deposition parameters, annealing, and hydrogen concentration”, J. vac. sci. technol., B Vol 8, (1990), pp. 533-539). As described above, the gate insulating film 31 is buried in the depression portions of the polysilicon layer 2. The polysilicon layer 2 is covered by the first gate insulating film 31.

Then, a planarization process is applied on the first gate insulating film 31. As for the planarization process, the CMP method is used, for example. A slurry (abrasive) used in the CMP method must be the one most suitable to the material of the first gate insulating film 31. If the first gate insulating film 31 is a silicon oxide film, a slurry of ceria (cerium oxide) is used, for example. To detect an end point of the CMP process, usually a current monitor of a turntable drive motor is used. However, desirably an optical thickness monitor of an in situ detection is used. It is desirable to apply the planarizing process until a RMS (Root Mean Square) value in 100 μm² area of the surface roughness of the first gate insulating film 31 becomes 10 nm or less and the average film thickness of the polysilicon layer 2 becomes 50 nm. By this, the projecting portions on the surface of the polysilicon layer 2 are exposed and the configuration as shown in FIG. 3D is created. As described above, the projecting portions of the polysilicon layer 2 are removed and the roughness on the first gate insulating film 31 becomes smooth. Moreover, the surface of the polysilicon layer 2 including the planarized first gate insulating film 31 has substantially the same height as the first gate insulating film 31 formed over the tapered pattern edge of the polysilicon layer 2 and over the insulating substrate 1 in the pattern peripheral parts of the polysilicon layer 2. Additionally, the surface of the projecting portions of the polysilicon layer 2, the surface of the first gate insulating film 31 provided in the depression portions of the polysilicon layer 2 and the surface of the first gate insulating film 31 in the tapered pattern edge and pattern peripheral portions of the polysilicon layer 2 have the polished surface with same height. That is, the entire surface of the first gate insulating film 31 becomes flat to be in parallel to the insulating substrate 1.

After the planarizing process for the first gate insulating film 31, the second gate insulating film 32 is formed over the removed surface including the polysilicon layer 2 and the first gate insulating film 31 as shown in FIG. 3E. The thickness of the second gate insulating film 32 is for example approx. 100 nm, however the thickness can be optimized according to the performance of the TFT. The second gate insulating film 32 is preferably an oxide film containing a large amount of hydrogen so as to reduce trap level density in the interface with the polysilicon layer 2, as with the first gate insulating film 31. For example, when using the plasma enriched CVD by TEOS (Tetra Ethyl Ortho Silicate) and oxygen, a silicon oxide film containing a hydrogen content of about 4 mol % can be formed (by Nguyen and Murarka). In this way, the gate insulating film 3 composed of the first gate insulating film 31 and the second gate insulating film 32 is formed. As the polysilicon layer 2 is exposed, the second gate insulating film 32 is formed to be in contact with the polysilicon layer 2.

A metal material to be the gate electrode is deposited over the gate insulating film 3 by sputtering and the gate electrode 4 is photo etched in a predetermined shape as shown in FIG. 3F. As for the gate electrode 4, a high melting point material such as Mo and Ti is used. Alternatively, it may be a stacked film with these high melting point materials as an upper layer and mainly using a low resistance material such as Al. As for the etching, either a dry or wet etching that is suitable to the material of the gate electrode 4 is used. Furthermore, an impurity is introduced to the source region 21 and the drain region 22. For example, for an n channel type TFT, the impurity to be introduced is an n type impurity such as phosphorus (P). As a method of introduction, ion implantation or ion doping method can be used. In order to reduce parasitic capacitance caused by an overlap of the gate electrode 4 and the source region 21, it is desirably made to be self-alignment structure. The impurity is introduced to the polysilicon layer 2 using the gate electrode 4 as a mask with the gate insulating film 3 interposed therebetween. The impurity is not introduced to the channel region 23.

Next, as in FIG. 3G, the interlayer insulating film 5 is formed over the gate electrode 4 and the second gate insulating film 32. The interlayer insulating film 5 is preferably a silicon nitride film for example so as to suppress hydrogen being diffused. After forming the interlayer insulating film 5, a heat treatment at 350 to 500 degree Celsius is applied. By the heat treatment, hydrogen contained in the oxide films such as the gate insulating film 3 is diffused and bonded to dangling bonds of silicon atoms present inside the polysilicon layer 2. This reduces the trap level that causes the TFT characteristics to be deteriorated. That is, the TFT characteristics such as Vth and carrier mobility are improved.

Furthermore, the contact holes are formed in the gate insulating film 3 and the interlayer insulating film 5 so that the source region 21 and the drain region 22 are exposed. Then, a conductive film such as Al or an alloy thereof is formed over the interlayer insulating film 5. By patterning the conductive film by usual photolithography or the like, the wiring layer 6 is formed as in FIG. 3H. The wiring layer 6 becomes the source lines 44 shown in FIG. 1, for example. After the abovementioned processes, the TFT 50 of this embodiment is completed.

As described above, in this embodiment of the present invention, the gate insulating film 3 is composed of two layers, which are the first gate insulating film 31 and second gate insulating film 32. Moreover, the first gate insulating film 31 is formed substantially all over the insulating substrate 1 to cover the polysilicon layer 2. Then, by the planarization process, the entire surface of the first gate insulating film 31 is removed to be substantially flat until the surface of the polysilicon layer 2 is exposed to some extent. By this, the projecting portions on the surface of the polysilicon layer 2 are removed and planarized. Thus the film thickness of the gate insulating film 3 can be formed to substantially even. Therefore, the gate withstand voltage is improved, thereby improving the yield and reliability of TFT products.

After the planarization process, the surface of the gate insulating film 31 becomes substantially flat virtually all over the insulating substrate 1. More specifically, the gate insulating film 31 formed in the tapered portions of the polysilicon layer 2 has substantially the same height as the central portion of the polysilicon layer 2. Furthermore, the second gate insulating film 32 is formed over the removed surface including the polysilicon layer 2 and the first gate insulating film 31. Therefore, the gate insulating film 3 formed in the tapered portions of the polysilicon layer 2 is thicker than the normal film thickness portions. This suppresses thin film effects in the tapered portions of the polysilicon film thickness t_{Si} in the formula (1). Additionally, in the subthreshold characteristics, a hump can be suppressed from generating and a stable threshold voltage Vth of the TFT can be achieved. Furthermore, the entire surface of the gate insulating film 31 including the polysilicon layer 2 becomes substantially flat and by forming the second gate insulating film 32 thereover, the tapered portions of the polysilicon layer 2 is completely covered by the gate insulating film 3. This resolves the failures of the gate insulating withstand voltage that is caused by the tapered portions of the polysilicon layer 2.

Moreover, in this embodiment of the present invention, the planarization process is not applied directly on the polysilicon layer 2 but applied on the first gate insulating film 31 until the surface of the polysilicon layer 2 is exposed from there to some extent. Therefore, the control of the film thickness of the polysilicon layer 2 is easy and variations in the film thickness can be suppressed. Then as indicated in the formula (1), Vth is stabled.

In the present invention, an illustrative case is described, in which the first gate insulating film 31 and polysilicon layer 2 are planarized by the CMP method, however they may be planarized by an etch back. Firstly, a planarization film with high planarizability is coated over the first gate insulating film 31. By using a photoresist used in a transfer process as the planarizing film, special equipments are not required to be introduced. As a patterning is unnecessary, a base resin not containing a photosensitive agent can be used as the planarizing film. Moreover, an organic SOG, organic SOD or inorganic SOG used as an insulating film material of multilayer interconnection may be used. As for the etch back, a method is selected, in which etching speeds of etched materials are substantially same. For example, as a method in which the etching speeds for the polysilicon layer 2, gate insulating film 31 and planarizing film are close, a RIE using C₃F₈, C₂F₆ and CHF₃ gas is performed. However, when using these gas, many contaminants are attached. Thus after the etch back, the surface of the gate insulating film 31 must be cleaned very well. As with the CMP method, the gate insulating film 31 having projecting portions of the polysilicon layer 2 can be planarized by this.

Furthermore in this embodiment of the present invention, an illustrative case is described, in which the interlayer insulating film 5 is formed by a film for suppressing the diffusion of hydrogen, it may be formed by a film containing a large amount of hydrogen. In such case, an upper insulating layer (not shown) covering the interlayer insulating film 5 and the wiring layer 6 is formed by a film to suppress the diffusion of hydrogen. Furthermore, after forming the upper insulating layer (not shown), a heat treatment at 350 to 500 degree Celsius is applied. By this, the same advantageous effects as when forming the interlayer insulating film 5 by a film for suppressing the diffusion of hydrogen. That is, the trap level is reduced and the TFT characteristics are improved.

The present invention explained the TFT with self-aligned structure as an example, however it may be a TFT with LDD structure including GOLD structure. In either case, the same advantageous effects can be achieved as the TFT with self-aligned structure.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor array substrate comprising:
a polysilicon layer having a predetermined pattern shape formed over a substrate;
a first gate insulating film provided over the substrate and on a surface of the polysilicon layer and having a same polished surface as the surface of the polysilicon layer; and
a second gate insulating film formed to cover the polysilicon layer and the first gate insulating film.

2. The thin film transistor array substrate according to claim 1, wherein the first gate insulating film in a pattern peripheral portion of the polysilicon layer has a substantially same height as the surface of the polysilicon layer.

3. The thin film transistor array substrate according to claim 1, wherein the first gate insulating film and the second gate insulating film include oxide silicon.

4. The thin film transistor array substrate according to claim 1, wherein the second gate insulating film includes 1 mol % or more of hydrogen.

5. The thin film transistor array substrate according to claim 1, wherein an edge portion in a predetermined pattern shape of the polysilicon layer is formed in taper.

6. A display device comprising the thin film transistor array substrate of claim 1.

7. A thin film transistor array substrate comprising:
a polysilicon layer having a predetermined pattern shape formed over a substrate;
a first gate insulating film provided over the substrate and on a surface of the polysilicon layer, a surface of the first gate insulating film having a substantially same height as the surface of the polysilicon layer, and a surface of the first gate insulating film over a pattern edge portion and a pattern peripheral portion of the polysilicon layer having a substantially same height as the surface of the polysilicon layer; and
a second gate insulating film formed to cover the polysilicon layer and the first gate insulating film.

8. The thin film transistor array substrate according to claim 7, wherein the first gate insulating film and the second gate insulating film include oxide silicon.

9. The thin film transistor array substrate according to claim 7, wherein the second gate insulating film includes 1 mol % or more of hydrogen.

10. The thin film transistor array substrate according to claim 7, wherein an edge portion in a predetermined pattern shape of the polysilicon layer is formed in taper.

11. A display device comprising the thin film transistor array substrate of claim 7.

12. A method of manufacturing a thin film transistor array substrate comprising:
forming a polysilicon layer with a rough surface over a substrate;
processing the polysilicon layer to be in a predetermined pattern shape;
depositing a first gate insulating film to cover the polysilicon layer;
planarizing by removing the first gate insulating film and the polysilicon layer until the surface of the polysilicon layer is exposed; and
forming a second gate insulating film over the removed first gate insulating film to cover the polysilicon layer and the first gate insulating film.

13. The method according to claim 12, wherein in the planarization process of the first gate insulating film and the polysilicon layer, a chemical mechanical polishing is used.

14. The method according to claim 12, wherein the planarization process of the first gate insulating film and the polysilicon layer comprises:
coating a planarizing film over the first gate insulating film; and
etching the first gate insulating film and the polysilicon layer together with the planarizing film to planarize until the surface of the polysilicon layer is exposed.

15. The method according to claim 12, wherein oxide silicon is used as the first gate insulating film and the second gate insulating film.

16. The method according to claim 12, wherein the second gate insulating film contains 1 mol % or more of hydrogen.

17. The method according to claim 15, wherein the first gate insulating film and the second gate insulating film are formed by a CVD using TEOS.
